(19) United States
(12) Patent Application Publication
(10) Pub. No.: US 2021/0249570 A1
(43) Pub. Date: Aug. 12, 2021

(54) LED CHIP PACKAGE STRUCTURE AND METHOD OF MANUFACTURING THE SAME

(71) Applicant: ASTI GLOBAL INC., TAIWAN, Taichung City (TW)

(72) Inventor: CHIEN-SHOU LIAO, New Taipei City (TW)

(21) Appl. No.: 17/029,126

(22) Filed: Sep. 23, 2020

(30) Foreign Application Priority Data
Feb. 10, 2020 (TW) 109103995

(51) Int. Cl. H01L 33/50; H01L 33/52; H01L 33/00

(52) U.S. Cl. CPC H01L 33/505; H01L 2933/0041; H01L 33/0095; H01L 33/52

(57) ABSTRACT

An LED chip package structure and a method of manufacturing the same are provided. The method includes providing a light wavelength converting film including a temporary substrate and a wavelength converting layer formed on the temporary substrate, removing the temporary substrate from the wavelength converting layer, and covering a plurality of LED chips by the wavelength converting layer. The LED chip package structure includes a plurality of LED chips and a wavelength converting layer covering the LED chips. The wavelength converting layer includes a plurality of red portions, a plurality of green portions, a plurality of transparent portions, and a black portion surrounding the red portions, the green portions and the transparent portions. Each of the red portions includes a plurality of red particles directly contacting the corresponding LED chip, and each of the green portions includes a plurality of green particles directly contacting the corresponding LED chip.

### CROSS-REFERENCE TO RELATED PATENT APPLICATION

This application claims the benefit of priority to Taiwan Patent Application No. 109103995, filed on Feb. 10, 2020. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a chip package structure and a method of manufacturing the same, and more particularly to an LED chip package structure and a method of manufacturing the same.

### BACKGROUND OF THE DISCLOSURE

In the prior art, a phosphor resin is formed by mixing phosphor particles and a package material, and then a light-emitting diode (LED) chip can be covered by the phosphor resin with the phosphor particles.

### SUMMARY OF THE DISCLOSURE

In response to the above-referenced technical inadequacies, the present disclosure provides an LED chip package structure and a method of manufacturing the same.

In one aspect, the present disclosure provides a method of manufacturing an LED chip package structure, including: providing a light wavelength converting film including a temporary substrate and a wavelength converting layer formed on the temporary substrate, wherein the wavelength converting layer includes a plurality of red portions staggered with respect to each other, a plurality of green portions staggered with respect to each other, a plurality of transparent portions staggered with respect to each other, and a black portion surrounding the red portions, the green portions and the transparent portions; placing the wavelength converting layer on a surface of a liquid in a liquid tank; using a solvent to dissolve the temporary substrate so as to remove the temporary substrate from the wavelength converting layer; and then performing a step (A) or a step (B). The step (A) includes gradually leaking the liquid away from the liquid tank so as to make the wavelength converting layer gradually approach a plurality of LED chips that have been disposed on a bottom surface inside the liquid tank in advance until a top surface of each of the LED chips is covered by the wavelength converting layer. The step (B) includes gradually raising a plurality of LED chips that have been disposed inside the liquid tank in advance by a lifting device so as to make the LED chips gradually approach the wavelength converting layer until a top surface of each of the LED chips is covered by the wavelength converting layer.

In another aspect, the present disclosure provides a method of manufacturing an LED chip package structure, including providing a light wavelength converting film including a temporary substrate and a wavelength converting layer formed on the temporary substrate, removing the temporary substrate from the wavelength converting layer, and covering a plurality of LED chips by the wavelength converting layer.

Furthermore, the step of removing the temporary substrate from the wavelength converting layer further including placing the wavelength converting film on a first position, wherein the first position is located on a surface of a first liquid in a first liquid tank, and using a solvent to dissolve the temporary substrate so as to remove the temporary substrate from the wavelength converting layer.

Furthermore, the step of covering the LED chips by the wavelength converting layer further including: placing the wavelength converting layer on a second position, the second position being a surface of a second liquid in a second liquid tank; and then gradually leaking the second liquid away from the second liquid tank so as to make the wavelength converting layer gradually approach the LED chips that have been disposed on a bottom surface inside the second liquid tank in advance until a top surface of each of the LED chips is covered by the wavelength converting layer.

Furthermore, the step of covering the LED chips by the wavelength converting layer further including: placing the wavelength converting layer on a second position, the second position being a surface of a second liquid in a second liquid tank; and then gradually raising the LED chips that have been disposed inside the second liquid tank in advance by a lifting device so as to make the LED chips gradually approach the wavelength converting layer until a top surface of each of the LED chips is covered by the wavelength converting layer.

Furthermore, the step of covering the LED chips by the wavelength converting layer further including: gradually leaking the first liquid away from the first liquid tank so as to make the wavelength converting layer gradually approach the LED chips that have been disposed on a bottom surface inside the first liquid tank in advance until a top surface of each of the LED chips is covered by the wavelength converting layer.

Furthermore, the step of covering the LED chips by the wavelength converting layer further including: gradually raising the LED chips that have been disposed inside the first liquid tank in advance by a lifting device so as to make the LED chips gradually approach the wavelength converting layer until a top surface of each of the LED chips is covered by the wavelength converting layer.

In yet another aspect, the present disclosure provides an LED chip package structure, including a plurality of LED chips and a wavelength converting layer covering the LED chips. The wavelength converting layer includes a plurality of red portions, a plurality of green portions, a plurality of transparent portions, and a black portion surrounding the red portions, the green portions and the transparent portions. A top surface of each of the LED chips is covered by one of the red portion, the green portion and the transparent portion and is not covered by the black portion. Each of the red portions includes a plurality of red particles directly contacting the corresponding LED chip, each of the green portions includes a plurality of green particles directly contacting the corresponding LED chip, and the wavelength converting layer is formed without non-wavelength converting material.

Therefore, by virtue of “providing a light wavelength converting film including a temporary substrate and a wavelength converting layer formed on the temporary substrate”, “removing the temporary substrate from the wavelength converting layer” and “covering a plurality of LED chips by the wavelength converting layer”, a plurality of red particles can directly contact the corresponding LED chip, and a plurality of green particles can directly contact the corresponding LED chip.

Furthermore, by virtue of “the wavelength converting layer covering the LED chips”, “the wavelength converting layer including a plurality of red portions, a plurality of green portions, a plurality of transparent portions, and a black portion surrounding the red portions, the green portions and the transparent portions” and “the top surface of each of the LED chips is covered by one of the red portion, the green portion and the transparent portion and is not covered by the black portion”, each of the red portions includes a plurality of red particles directly contacting the corresponding LED chip, and each of the green portions includes a plurality of green particles directly contacting the corresponding LED chip.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The present disclosure will become more fully understood from the following detailed description and accompanying drawings.

FIG. 1 is a flowchart of a method of manufacturing an LED chip package structure.

FIG. 2 is a schematic view of a wavelength converting film according to a first embodiment of the present disclosure, and is also a schematic view of step S100 of a method of manufacturing an LED chip package structure according to the first embodiment of the present disclosure.

FIG. 3 is a cross-sectional schematic view taken along line II-II of FIG. 2.

FIG. 4 shows an enlarged schematic view of part IV of FIG. 3.

FIG. 5 is a schematic view of step S1022 of the method of manufacturing the LED chip package structure according to the first embodiment of the present disclosure.

FIG. 6 is a schematic view of step S102 and step S1024 of the method of manufacturing the LED chip package structure according to the first embodiment of the present disclosure.

FIG. 7 is a schematic view of step S1042 of the method of manufacturing the LED chip package structure according to the first embodiment of the present disclosure.

FIG. 8 is a schematic view of step S104 of the method of manufacturing the LED chip package structure according to the first embodiment of the present disclosure.

FIG. 9 is a schematic view of step S1044(A) of the method of manufacturing the LED chip package structure being performing according to the first embodiment of the present disclosure.

FIG. 10 is a schematic view of step S1044(A) of the method of manufacturing the LED chip package structure having been performed according to the first embodiment of the present disclosure.

FIG. 11 is a schematic view of the LED chip package structure according to the first embodiment of the present disclosure.

FIG. 12 is a schematic view of step S1044(B) of a method of manufacturing an LED chip package structure being performing according to a second embodiment of the present disclosure.

FIG. 13 is a schematic view of step S1044(B) of the method of manufacturing the LED chip package structure having been performed according to the second embodiment of the present disclosure.

FIG. 14 is a schematic view of a wavelength converting layer disposed on a surface of a first liquid in a first liquid tank according to a third embodiment of the present disclosure.

FIG. 15 is a schematic view of a solvent being used to dissolve a temporary substrate so as to remove the temporary substrate from the wavelength converting layer according to the third embodiment of the present disclosure.

FIG. 16 is a schematic view of step S1040(A) of a method of manufacturing an LED chip package structure according to the third embodiment of the present disclosure.

FIG. 17 is a schematic view of step S1040(B) of a method of manufacturing an LED chip package structure according to a fourth embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

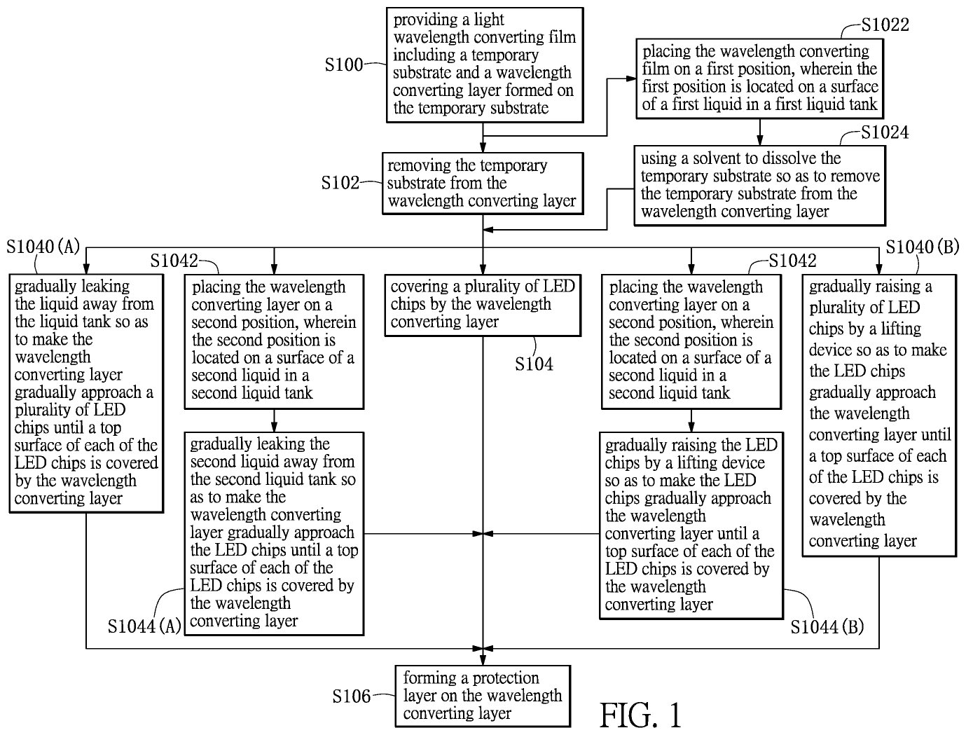

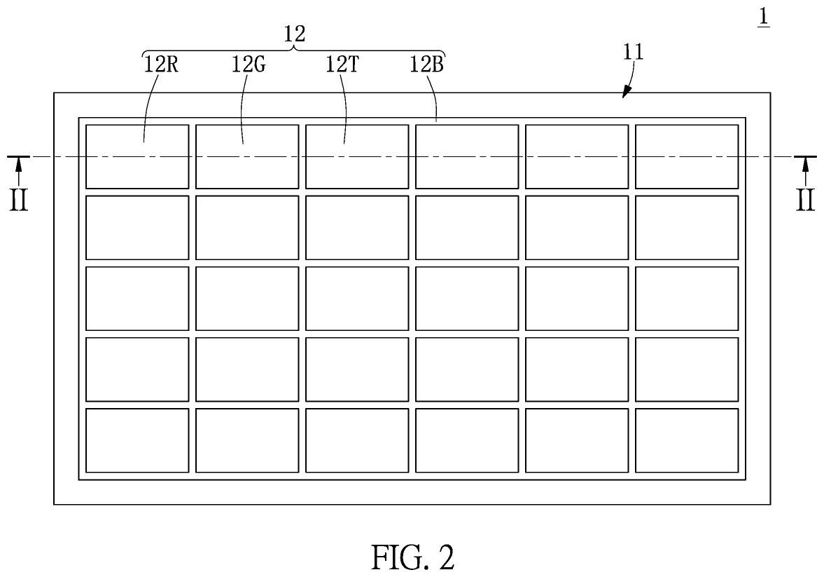

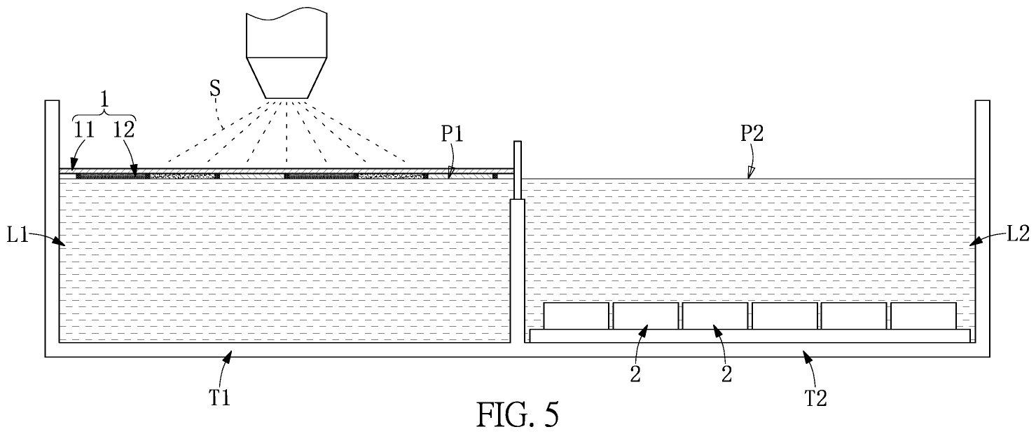

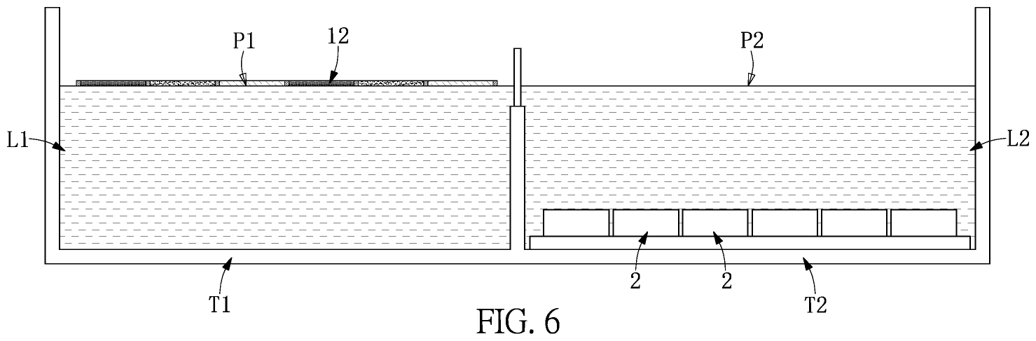

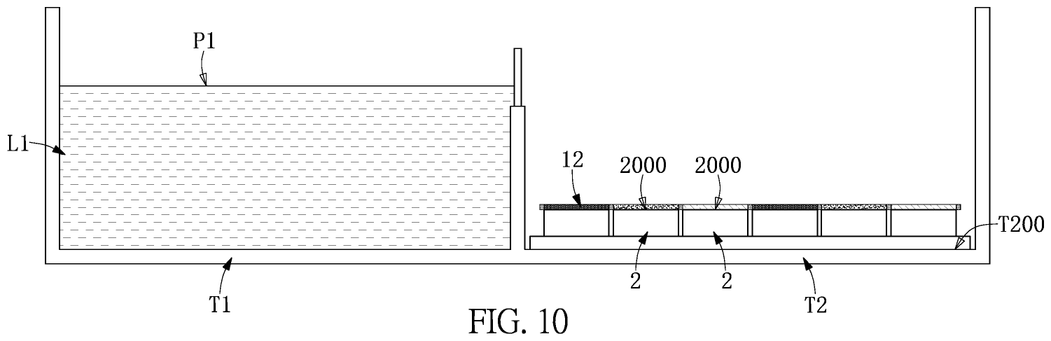

Referring to FIG. 1 to FIG. 11, a first embodiment of the present disclosure provides a method of manufacturing an LED chip package structure, including: firstly, referring to FIG. 1 to FIG. 3, providing a light wavelength converting film 1 including a temporary substrate 11 and a wavelength converting layer 12 formed on the temporary substrate 11 (step S100); next, referring to FIG. 1, FIG. 5 and FIG. 6, removing the temporary substrate 11 from the wavelength converting layer 12 (step S102); and then referring to FIG. 1 and FIG. 10, covering a plurality of LED chips 2 by the wavelength converting layer 12 (step S104).

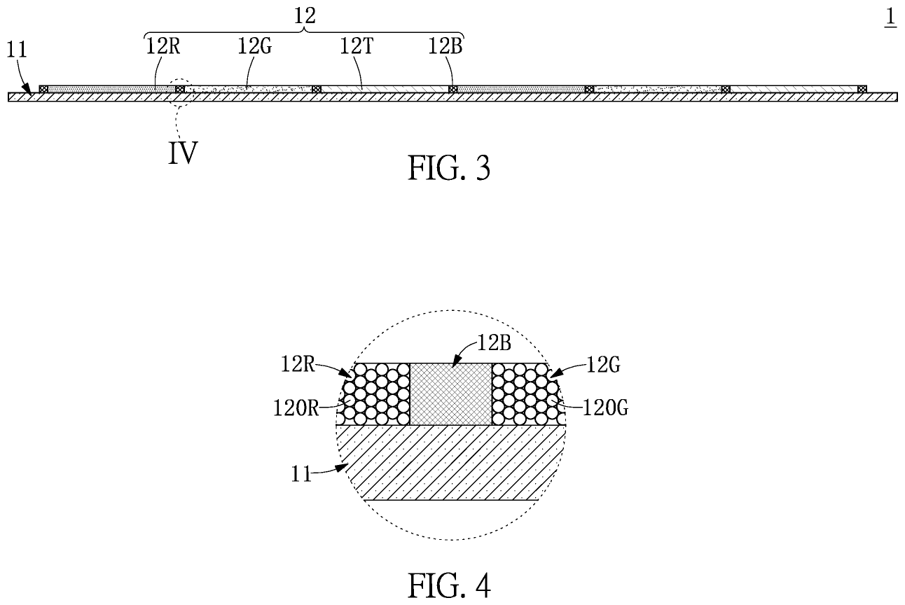

For example, referring to FIG. 3 and FIG. 4, the wavelength converting layer 12 can be formed on the temporary substrate 11 by printing, coating or spraying etc., and the wavelength converting layer 12 includes a plurality of red portions 12R staggered or non-staggered with respect to each other, a plurality of green portions 12G staggered or non-staggered with respect to each other, a plurality of transparent portions 12T staggered or non-staggered with respect to each other, and a black portion 12B surrounding the red portions 12R, the green portions 12G and the transparent portions 12T. Moreover, a red slurry with a plurality of red particles 120R (such as polyvinyl alcohol (PVA) with red phosphor particles or red quantum dot particles) can be printed, coated or sprayed to form the red portion 12R with the red particles 120R. A green slurry with a plurality of green particles 120G (such as polyvinyl alcohol (PVA) with green phosphor particles or green quantum dot particles) can be printed, coated or sprayed to form the green portion 12G with the green particles 120G. The transparent portions 12T can be made of any transparent material (such as transparent polyvinyl alcohol) by printing, coating or spraying, and the black portion 12B can be made of black material (such as black ink) by printing, coating or spraying. However, the aforementioned description is merely an example and is not meant to limit the scope of the present disclosure.

For example, after the top surfaces of the LED chips 2 are covered by the wavelength converting layer 12, the method further includes forming a protection layer (not shown) on the wavelength converting layer 12 (step S106). However, the aforementioned description is merely an example and is not meant to limit the scope of the present disclosure. That is to say, the protection layer can be omitted in the method of manufacturing the LED chip package structure.

For example, referring to FIG. 1, FIG. 5 and FIG. 6, the step S102 of removing the temporary substrate 11 from the wavelength converting layer 12 further includes: firstly, referring to FIG. 1 and FIG. 5, placing the wavelength converting film 1 on a first position P1, wherein the first position P1 is located on a surface of a first liquid L1 in a first liquid tank T1 (step S1022); and then referring to FIG. 1, FIG. 5 and FIG. 6, using a solvent S to dissolve the temporary substrate 11 so as to remove the temporary substrate 11 from the wavelength converting layer 12 (step S1024). It should be noted that the red slurry (such as including PVA) can be dissolved except for the red particles 120R, and the green slurry (such as including PVA) can be dissolved except for the green particles 120G. More particularly, the first liquid L1 may be water or other liquid similar to water. In addition, the temporary substrate 11 may be made of any type of water-soluble material or non-water-soluble material. The water-soluble material may be a water soluble macromolecular polymer such as PVA that can be dissolved by glycerine or phenol etc. However, the aforementioned description is merely an example and is not meant to limit the scope of the present disclosure.

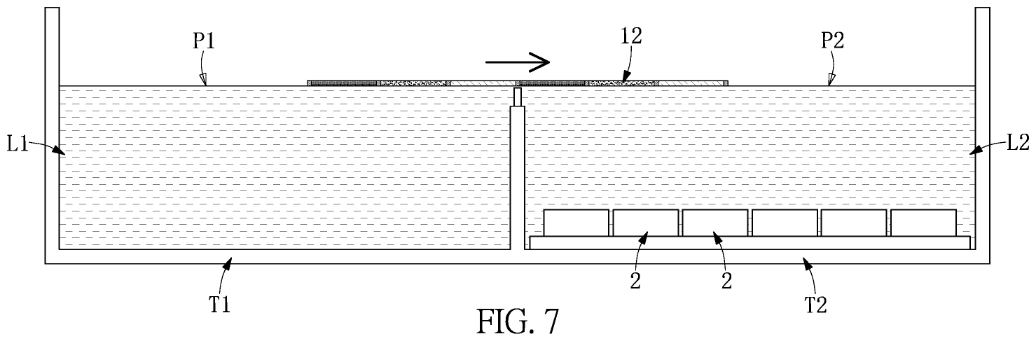

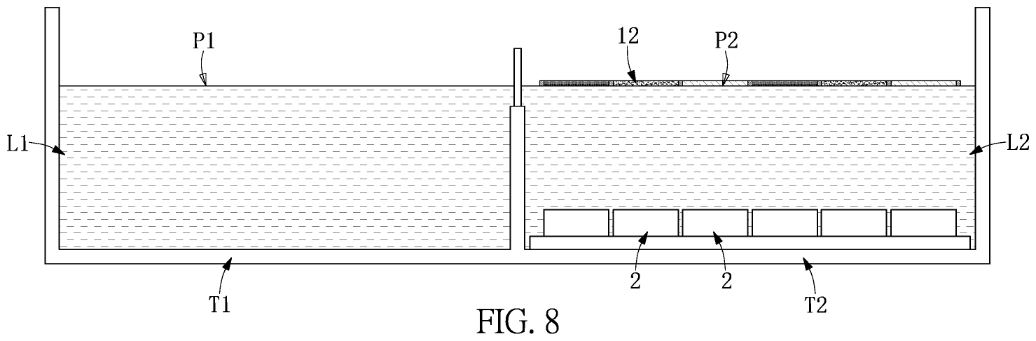

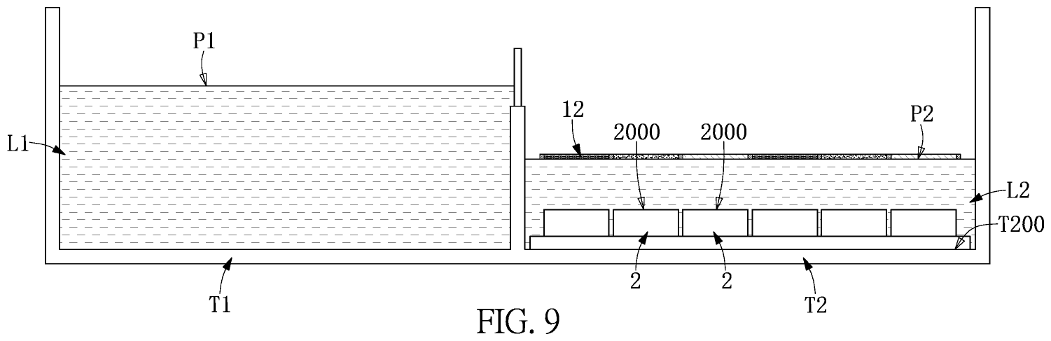

For example, referring to FIG. 1 and FIG. 6 to FIG. 10, the step S104 of covering the LED chips 2 by the wavelength converting layer 12 further includes: firstly, referring to FIG. 1, FIG. 7 and FIG. 8, placing the wavelength converting layer 12 on a second position P2, wherein the second position P2 is located on a surface of a second liquid L2 in a second liquid tank T2 (step S1042); and then referring to FIG. 1, FIG. 9 and FIG. 10, gradually leaking (or removing) the second liquid L2 away from the second liquid tank T2 so as to make the wavelength converting layer 12 gradually approach (gradually close to) the LED chips 2 that have been disposed on a bottom surface T200 inside the second liquid tank T2 in advance until a top surface 2000 of each of the LED chips 2 is covered by the wavelength converting layer 12 (step S1044(A)). It should be noted that when the second liquid L2 is gradually leaked (or removed) from the second liquid tank T2, the wavelength converting layer 12 can be correctly positioned on the LED chips 2 through an image capturing device (such as a charge coupled device (CCD)). That is to say, one of the red portion 12R, the green portion 12G and the transparent portions 12T can be correctly positioned the on the top surface 2000 of each of the LED chips 2. Moreover, when the wavelength converting layer 12 is moved to the second position P2 as shown in FIG. 8, the temporary substrate 11 that has been removed from the wavelength converting layer 12 can be remained in the first liquid tank T1 or removed from the first liquid tank T1. In addition, the first liquid L1 and the second liquid L2 may be water or other liquid similar to water, and the first liquid L1 and the second liquid L2 may be the same or different liquid. However, the aforementioned description is merely an example and is not meant to limit the scope of the present disclosure.

For example, the step of forming the protection layer (not shown) on the wavelength converting layer 12 further includes: forming a projection material on the wavelength converting layer 12 so as to cover a top surface of the wavelength converting layer 12, and then curing the projection material to form the protection layer (not shown) for covering the wavelength converting layer 12 by lighting or heating. However, the aforementioned description is merely an example and is not meant to limit the scope of the present disclosure.

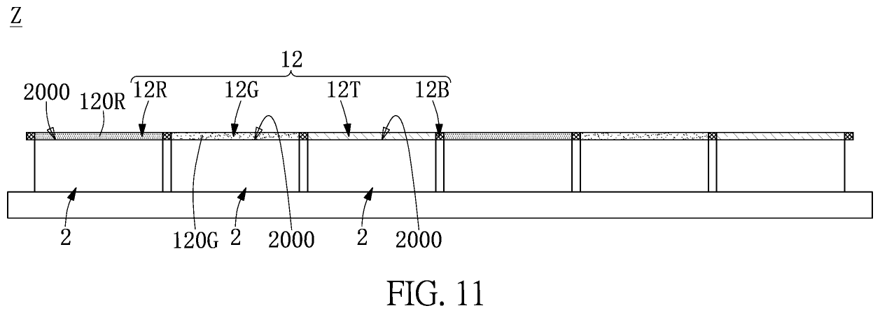

Therefore, referring to FIG. 11, the first embodiment of the present disclosure provides an LED chip package structure Z, including a plurality of LED chips 2 and a wavelength converting layer 12 covering the LED chips 2. More particularly, the wavelength converting layer 12 includes a plurality of red portions 12R, a plurality of green portions 12G, a plurality of transparent portions 12T, and a black portion 12B surrounding the red portions 12R, the green portions 12G and the transparent portions 12T. In addition, a top surface 2000 of each of the LED chips 2 is covered by one of the red portion 12R, the green portion 12G and the transparent portion 12T and is not covered by the black portion 12B. Moreover, each of the red portions 12R includes a plurality of red particles 120R tightly connected with each other (as shown in FIG. 4), and each of the green portions 12G includes a plurality of green particles 120G tightly connected with each other (as shown in FIG. 4). The wavelength converting layer 12 excludes non-wavelength converting material (that is to say, the wavelength converting layer 12 is formed without non-wavelength converting material), so that the red particles 120R can directly contact the corresponding LED chip 2, and the green particles 120G can directly contact the corresponding LED chip 2.

For example, the LED chip package structure Z further includes a protection layer (not shown) formed on the wavelength converting layer 12. More particularly, the top surfaces 2000 of the LED chips 2 can be covered by the wavelength converting layer 12, and the wavelength converting layer 12 can be covered by the protection layer (not shown). However, the aforementioned description is merely an example and is not meant to limit the scope of the present disclosure.

### Second Embodiment

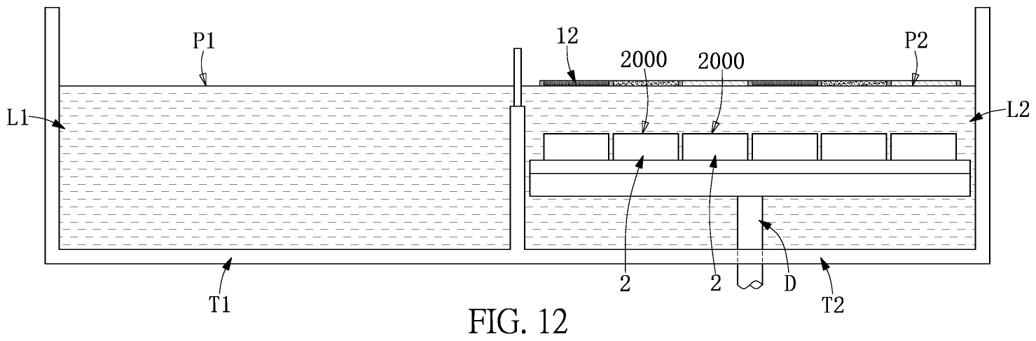

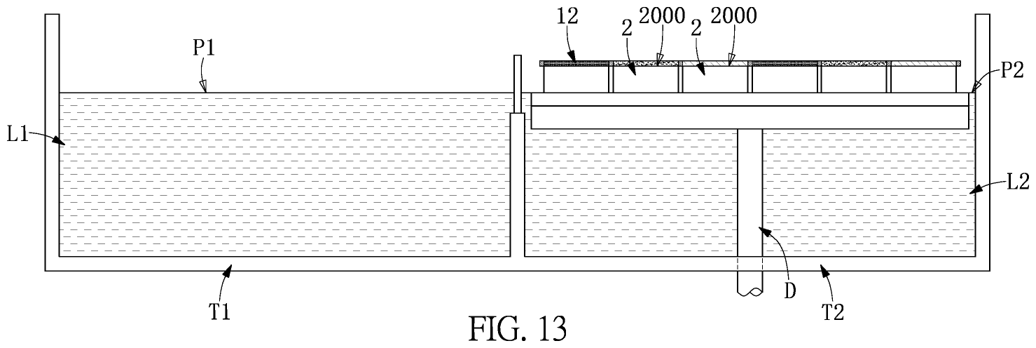

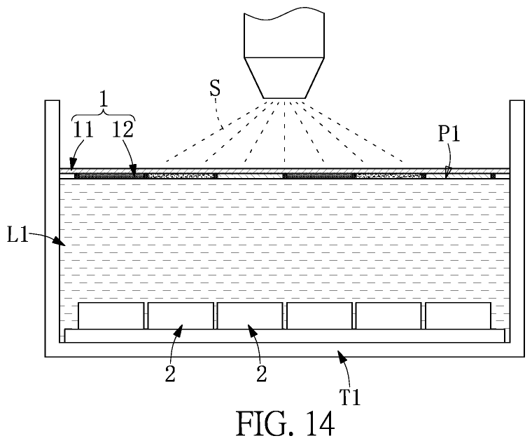

Referring to FIG. 12 and FIG. 13, a second embodiment of the present disclosure provides a method of manufacturing an LED chip package structure. Comparing FIG. 12 with FIG. 9, and comparing FIG. 13 with FIG. 10, the difference between the second embodiment and the first embodiment is as follows: in the second embodiment, the method of manufacturing the LED chip package structure includes gradually raising the LED chips 2 that have been disposed inside the second liquid tank T2 in advance by a lifting device D so as to make the LED chips 2 gradually approach the wavelength converting layer 12 until a top surface 2000 of each of the LED chips 2 is covered by the wavelength converting layer 12 (step S1044(B)). That is to say, the step S1044(A) of the first embodiment can be replaced by the step S1044(B) of the second embodiment according to different requirements. Hence, by virtue of “gradually leaking the second liquid L2 away from the second liquid tank T2 so as to make the wavelength converting layer 12 gradually approach the LED chips 2” or “gradually raising the LED chips 2 by the lifting device D so as to make the LED chips 2 gradually approach the wavelength converting layer 12”, the top surface 2000 of the LED chips 2 can be covered by the wavelength converting layer 12. However, the aforementioned description is merely an example and is not meant to limit the scope of the present disclosure.

It should be noted that when the LED chips 2 gradually approach the wavelength converting layer 12 by the lifting device D, the wavelength converting layer 12 can be correctly positioned on the LED chips 2 through an image capturing device (such as a charge coupled device (CCD)). That is to say, one of the red portion 12R, the green portion 12G and the transparent portions 12T can be correctly positioned the on the top surface 2000 of each of the LED chips 2.

### Third Embodiment

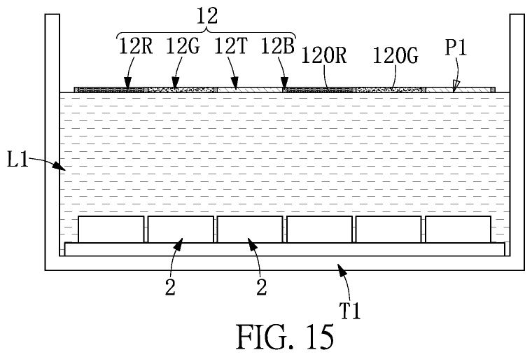

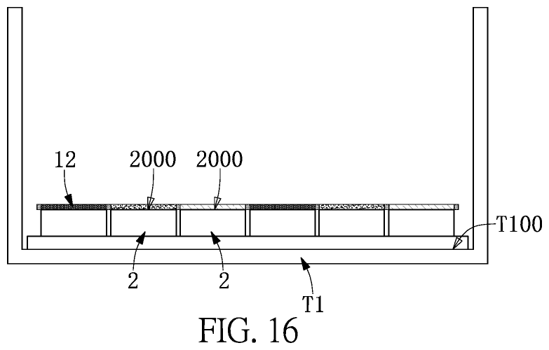

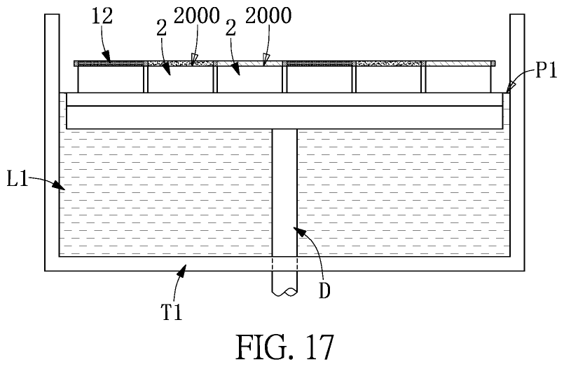

Referring to FIG. 14 to FIG. 16, a third embodiment of the present disclosure provides a method of manufacturing an LED chip package structure, including: firstly, as shown in FIG. 14, providing a light wavelength converting film 1 including a temporary substrate 11 and a wavelength converting layer 12 formed on the temporary substrate 11; next, as shown in FIG. 14, placing the wavelength converting layer 1 on a surface of a liquid (such as a first liquid L1) in a liquid tank (such as a first liquid tank T1); and then referring to FIG. 14 and FIG. 15, using a solvent S to dissolve the temporary substrate 11 so as to remove the temporary substrate 11 from the wavelength converting layer 12. Comparing FIG. 16 with FIG. 10, the difference between the third embodiment and the first embodiment is as follows: in the third embodiment, the method of manufacturing the LED chip package structure includes gradually leaking the liquid (such as the first liquid L1) away from the liquid tank (such as the first liquid tank T1) so as to make the wavelength converting layer 12 gradually approach a plurality of LED chips 2 that have been disposed on a bottom surface T100 inside the liquid tank (such as the first liquid tank T1) in advance until a top surface 2000 of each of the LED chips 2 is covered by the wavelength converting layer 12 (step S1040(A)). Hence, the method of manufacturing the LED chip package structure can be applied to a single liquid tank (such as the first liquid tank T1) or two liquid tanks (such as the first liquid tank T1 and the second liquid tank T2). However, the aforementioned description is merely an example and is not meant to limit the scope of the present disclosure.

### Fourth Embodiment

Referring to FIG. 17, a fourth embodiment of the present disclosure provides a method of manufacturing an LED chip package structure. Comparing FIG. 17 with FIG. 16, the difference between the fourth embodiment and the third embodiment is as follows: in the fourth embodiment, the method of manufacturing the LED chip package structure includes gradually raising a plurality of LED chips 2 that have been disposed inside the liquid tank (such as the first liquid tank T1) in advance by a lifting device D so as to make the LED chips 2 gradually approach the wavelength converting layer 12 until a top surface 2000 of each of the LED chips 2 is covered by the wavelength converting layer 12 (step S1040(B)). Hence, by virtue of “gradually leaking the first liquid L1 away from the first liquid tank T1 so as to make the wavelength converting layer 12 gradually approach the LED chips 2” or “gradually raising the LED chips 2 by the lifting device D so as to make the LED chips 2 gradually approach the wavelength converting layer 12”, the top surface 2000 of the LED chips 2 can be covered by the wavelength converting layer 12. However, the aforementioned description is merely an example and is not meant to limit the scope of the present disclosure.

In conclusion, by virtue of “providing a light wavelength converting film 1 including a temporary substrate 11 and a wavelength converting layer 12 formed on the temporary substrate 11”, “removing the temporary substrate 11 from the wavelength converting layer 12” and “covering a plurality of LED chips 2 by the wavelength converting layer 12”, a plurality of red particles 120R can directly contact the corresponding LED chip 2, and a plurality of green particles 120G can directly contact the corresponding LED chip 2.

Furthermore, by virtue of “the wavelength converting layer 12 covering the LED chips 2”, “the wavelength converting layer 12 including a plurality of red portions 12R, a plurality of green portions 12G, a plurality of transparent portions 12T, and a black portion 12B surrounding the red portions 12R, the green portions 12G and the transparent portions 12T” and “the top surface 2000 of each of the LED chips 2 is covered by one of the red portion 12R, the green portion 12G and the transparent portion 12T and is not covered by the black portion 12B”, each of the red portions 12R includes a plurality of red particles 120R directly contacting the corresponding LED chip 2, and each of the green portions 12G includes a plurality of green particles 120G directly contacting the corresponding LED chip 2.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A method of manufacturing an LED chip package structure, comprising:
providing a light wavelength converting film including a temporary substrate and a wavelength converting layer formed on the temporary substrate, wherein the wavelength converting layer includes a plurality of red portions staggered with respect to each other, a plurality of green portions staggered with respect to each other, a plurality of transparent portions staggered with respect to each other, and a black portion surrounding the red portions, the green portions and the transparent portions;
placing the wavelength converting layer on a surface of a liquid in a liquid tank;
using a solvent to dissolve the temporary substrate so as to remove the temporary substrate from the wavelength converting layer; and
performing a step (A) or a step (B);
wherein the step (A) includes gradually leaking the liquid away from the liquid tank so as to make the wavelength converting layer gradually approach a plurality of LED chips that have been disposed on a bottom surface inside the liquid tank in advance until a top surface of each of the LED chips is covered by the wavelength converting layer;
wherein the step (B) includes gradually raising a plurality of LED chips that have been disposed inside the liquid tank in advance by a lifting device so as to make the LED chips gradually approach the wavelength converting layer until a top surface of each of the LED chips is covered by the wavelength converting layer.

2. The method according to claim 1, wherein after the top surfaces of the LED chips are covered by the wavelength converting layer, the method further comprises forming a protection layer on the wavelength converting layer; wherein when the top surfaces of the LED chips are covered by the wavelength converting layer, the top surface of each of the LED chips is covered by one of the red portion, the green portion and the transparent portion and is not covered by the black portion; wherein each of the red portions includes a plurality of red particles tightly connected with each other, and each of the green portions includes a plurality of green particles tightly connected with each other.

3. A method of manufacturing an LED chip package structure, comprising:
providing a light wavelength converting film including a temporary substrate and a wavelength converting layer formed on the temporary substrate;
removing the temporary substrate from the wavelength converting layer; and
covering a plurality of LED chips by the wavelength converting layer.

4. The method according to claim 3, wherein the step of removing the temporary substrate from the wavelength converting layer further comprises:
placing the wavelength converting film on a first position, wherein the first position is located on a surface of a first liquid in a first liquid tank; and
using a solvent to dissolve the temporary substrate so as to remove the temporary substrate from the wavelength converting layer.

5. The method according to claim 4, wherein the step of covering the LED chips by the wavelength converting layer further comprises:
placing the wavelength converting layer on a second position, wherein the second position is located on a surface of a second liquid in a second liquid tank; and
gradually leaking the second liquid away from the second liquid tank so as to make the wavelength converting layer gradually approach the LED chips that have been disposed on a bottom surface inside the second liquid tank in advance until a top surface of each of the LED chips is covered by the wavelength converting layer.

6. The method according to claim 4, wherein the step of covering the LED chips by the wavelength converting layer further comprises:
placing the wavelength converting layer on a second position, wherein the second position is located on a surface of a second liquid in a second liquid tank; and
gradually raising the LED chips that have been disposed inside the second liquid tank in advance by a lifting device until so as to make the LED chips gradually approach the wavelength converting layer a top surface of each of the LED chips is covered by the wavelength converting layer.

7. The method according to claim 4, wherein the step of covering the LED chips by the wavelength converting layer further comprises: gradually leaking the first liquid away from the first liquid tank so as to make the wavelength converting layer gradually approach the LED chips that have been disposed on a bottom surface inside the first liquid tank in advance until a top surface of each of the LED chips is covered by the wavelength converting layer.

8. The method according to claim 4, wherein the step of covering the LED chips by the wavelength converting layer further comprises: gradually raising the LED chips that have been disposed inside the first liquid tank in advance by a lifting device so as to make the LED chips gradually approach the wavelength converting layer until a top surface of each of the LED chips is covered by the wavelength converting layer.

9. An LED chip package structure, comprising:
a plurality of LED chips; and
a wavelength converting layer covering the LED chips;
wherein the wavelength converting layer includes a plurality of red portions, a plurality of green portions, a plurality of transparent portions, and a black portion surrounding the red portions, the green portions and the transparent portions;
wherein a top surface of each of the LED chips is covered by one of the red portion, the green portion and the transparent portion and is not covered by the black portion;
wherein each of the red portions includes a plurality of red particles directly contacting the corresponding LED chip, each of the green portions includes a plurality of green particles directly contacting the corresponding LED chip, and the wavelength converting layer is formed without non-wavelength converting material.

10. The LED chip package structure according to claim 9, further comprising a protection layer formed on the wavelength converting layer.
